(19) United States
(12) Patent Application Publication
(10) Pub. No.: US 2024/0362393 A1
(43) Pub. Date: Oct. 31, 2024

(54) PREDICTION OF ROUTING CONGESTION

(71) Applicant: Xilinx, Inc., San Jose, CA (US)

(72) Inventors: Apurva Abhijit Mirashi, Ichalkaranji (IN); Veeresh Pratap Singh, Kompally (IN); Meghraj Kalase, Hyderabad (IN); Srinivasan Dasasathyan, Secunderabad (IN)

(73) Assignee: Xilinx, Inc., San Jose, CA (US)

(21) Appl. No.: 18/139,659

(22) Filed: Apr. 26, 2023

(51) Int. Cl. G06F 30/394; G06F 30/31; G06F 30/323; G06F 30/327; G06F 30/392

(52) U.S. Cl. CPC G06F 30/394; G06F 30/31; G06F 30/323; G06F 30/327; G06F 30/392

(57) ABSTRACT

A congestion prediction machine learning model is trained to generate, prior to placement, a prediction value indicative of a congestion level likely to result from placement and routing of a netlist based on features of the netlist. In response to the prediction value indicating the congestion level is greater than a threshold, a design tool determines an implementation-flow action and performs the implementation-flow action to generate implementation data that is suitable for making an integrated circuit.

### TECHNICAL FIELD

The disclosure generally relates to predicting routing congestion before placing and routing a circuit design.

### BACKGROUND

Timing closure is one example of an important objective for Electronic Design Automation (EDA) tools in processing circuit designs targeted to application specific integrated circuit (ASICs), system on chips (SoCs), or field programmable gate arrays (FPGAs). Other examples of objectives include satisfying constraints relating to circuit area and power consumption.

In EDA tools, the behavior of the algorithms used for implementing and optimizing designs is highly non-linear and usually difficult to predict. The algorithms also involve objective, heuristic functions. A typical EDA tool consists of many such algorithms working in sequence, which is sometimes referred to as an “implementation flow” or “design flow.” Each step/algorithm in the sequence typically employs a heuristic to solve a specific problem. In some cases, a specific objective or cost function is used.

A typical implementation flow can take hours to produce a satisfactory realization of a circuit design, with a large portion of time devoted to placing and routing. During routing, congestion can result in long runtimes or make the design unroutable. Routing congestion is present when the design imposes a greater demand for routing resources within a given region of a target device than a supply of routing resources within that region.

### SUMMARY

A disclosed method includes synthesizing a circuit design into a netlist and identifying features from the netlist by a design tool. The method includes the design tool applying a congestion prediction model to the features prior to placement. The application of the congestion prediction model generates a prediction value indicative of a congestion level likely to result from placement and routing of the netlist. The includes the design tool, in response to the prediction value indicating the congestion level is greater than a threshold determining an implementation-flow action, and performing the implementation-flow action to generate implementation data that is suitable for making an integrated circuit (IC).

Another disclosed method includes synthesizing and performing logic optimization on circuit designs of a training set to generate respective netlists by a design tool. The method includes the design tool determining respective feature sets of the netlists and performing placement and routing on the netlists to generate placed-and-routed designs. The method includes the design tool determining respective congestion levels from the placed-and-routed designs and training a classification model using the respective features sets and respective congestion levels.

A disclosed system includes one or more computer processors and a memory arrangement coupled to the one or more computer processors. The one or more computer processors are configured to execute program code. The memory arrangement is configured with instructions of a design tool that when executed by the one or more computer processors cause the one or more computer processors to perform operations that includes synthesizing a circuit design into a netlist and identifying features from the netlist. The operations include applying a congestion prediction model to the features prior to placement. The application of the congestion prediction model generates a prediction value indicative of a congestion level likely to result from placement and routing of the netlist. Further operations performed in response to the prediction value indicating the congestion level is greater than a threshold include determining an implementation-flow action, and performing the implementation-flow action to generate implementation data that is suitable for making an integrated circuit (IC).

Other features will be recognized from consideration of the Detailed Description and Claims, which follow.

### BRIEF DESCRIPTION OF THE DRAWINGS

Various aspects and features of the methods and systems will become apparent upon review of the following detailed description and upon reference to the drawings in which:

FIG. 1 illustrates an implementation flow that predicts routing congestion after logic optimization and before commencing placement and routing phases;

FIG. 2 shows a flowchart of an exemplary process of a training tool for training one or more machine learning models to predict routing congestion in circuit designs;

FIG. 3 show a flowchart of an exemplary process by which a label can be generated in the training of a machine learning model for predicting routing congestion;

FIG. 4 shows an example of a first type of target IC device that can be implemented on a single semiconductor die;

FIG. 5 shows an example of a second type of target IC device that can be implemented on multiple semiconductor dice, such as a System-on-Chip (SoC); and

FIG. 6 is a block diagram illustrating an exemplary data processing system.

### DETAILED DESCRIPTION

In the following description, numerous specific details are set forth to describe specific examples presented herein. It should be apparent, however, to one skilled in the art, that one or more other examples and/or variations of these examples may be practiced without all the specific details given below. In other instances, well known features have not been described in detail so as not to obscure the description of the examples herein. For ease of illustration, the same reference numerals may be used in different diagrams to refer to the same elements or additional instances of the same element.

Addressing routing congestion prior to the placement stage of an implementation flow is particularly important for circuit designs targeted to integrated circuit (IC) devices having finite routing resources, because routing resources cannot be added to relieve the congestion. If left unresolved in earlier stages, such as in synthesis or logic optimization, longer delays and use of more routing resources may result. Longer delays can degrade the design performance, or the design may not be routable in a manner that satisfies timing constraints. Failure to satisfy timing constraints may force the designer to modify the circuit design and repeat the entire implementation flow.

According to the disclosed methods and systems, after a circuit design has been synthesized into a netlist by an EDA tool and before placing and routing the netlist, the EDA tool identifies features from the netlist and applies a congestion prediction model. Based on the identified features, the congestion prediction model generates a prediction value that indicates a level of congestion likely to result from placement and routing of the netlist. In response to finding that the prediction value indicates a high level of congestion, for example, by comparing the prediction value to a threshold, the EDA tool selects an implementation-flow action. The action can be modifying the circuit design source code (e.g., register transfer level) or netlist, or of selecting parameter settings that can be used with placement and routing. The EDA tool can then perform the implementation-flow action and other processes of the overall implementation flow to generate implementation data that is suitable for making an integrated circuit (IC). In response to finding that the prediction value indicates a low level of congestion, the EDA tool can bypass selecting an implementation-flow action and proceed to placement and routing of the netlist.

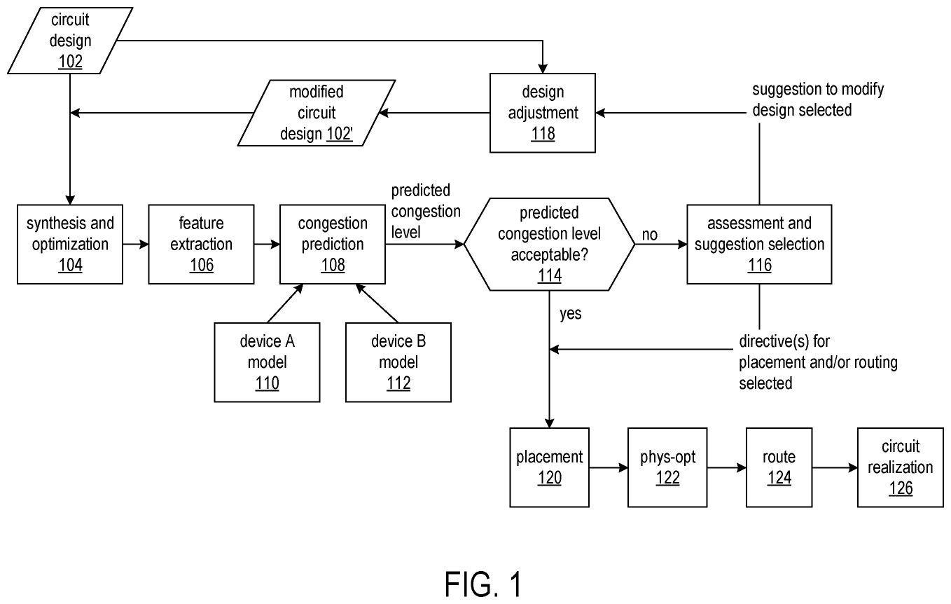

FIG. 1 illustrates an implementation flow that predicts routing congestion after logic optimization and before commencing placement and routing phases. Prediction of routing congestion early in the implementation flow can be used by an EDA tool (or “design tool”) to reduce computational requirements in the placement and routing phases. The design tool can reduce its use of computational resources by following two generally alternative courses of action. In response to finding the synthesized and logically optimized design (the “optimized design” for brevity) is likely to exhibit routing congestion, the design tool can automatically modify or make suggestions to modify the source circuit design and thereafter repeat synthesis and logic optimization. Alternatively, the design tool can automatically select sets of parameter settings (“directives”) or make suggestions of directives that can reduce routing congestion in placement and routing phases of the implementation flow. By modifying the design instead of proceeding to placement and routing phases with a version of the design likely to exhibit routing congestion, the design tool avoids placement and routing phases that would likely require an unacceptable level of computational resources to complete. By selecting or suggesting directives, the design tool can reduce the quantity of computational resources used to complete placement and routing phases.

The implementation flow of FIG. 1 begins with synthesis and optimization of circuit design 102 at block 104. The circuit design can be a register transfer level (RTL) version prepared from a high-level language description of the design, for example. The synthesis and optimization stages produce an optimized netlist.

Prior to commencing placement, the design tool can predict, based on features of the optimized netlist, whether or not an unacceptable level of routing congestion is likely to result from placement and routing. The design tool can automatically initiate the prediction, or alternatively, initiate the prediction in response to interactive control by the designer. According to an exemplary implementation, the prediction can be initiated by a tool command language (“Tcl”), as part of a general quality assessment evaluation, or via an application programming interface.

The optimized netlist can be is input to the feature extraction stage 106. The processes of the feature extraction stage identify four general types of features for training the machine learning models to predict routing congestion. The general types of features pertain to resource utilization, design elements, design run elements, and device elements, all of which can be identified using known tools. The design tool can use different machine learning (ML) models for different target devices as explained below.

The utilization features include levels of utilization of resources of the target IC device, such as configurable logic blocks (CLBs), flip-flops, carry logic, digital signal processors (DSPs), and memory resources. For a target IC device such as a field programmable gate array (FPGA), the memory resources can include block RAMs, ultra RAMS, and look-up table RAMS, such as those found in FPGA's from AMD, Inc.

The design features include an indicator based on high-fanout nets and interconnection complexity of the logical netlist. Nets that fan-out to drive large numbers of control pins in a particular region can lead to routing congestion. A high fanout net can be identified based the number of pins driven relative to a first threshold, and the indicator of high-fanout nets can be identified by finding the number of high-fanout nets in a region exceeds a second threshold.

The interconnection complexity of the logical netlist can be quantified by the Rent exponent in Rent's rule. The value of the Rent exponent can be determined from the optimized netlist. The features of the design run can include the worst negative slack (WNS) and worst hold slack (WHS). The features of the target IC device can include the number of processing systems in the device and the number of high-speed serial transceivers, for example.

Block 108 shows the congestion prediction stage that presents the features determined by the feature extraction process to the one of the ML models 110 or 112 that is applicable to the target IC device. Different types of target devices can have different device characteristics that can affect routing congestion. According to the disclosed methods and systems, separate ML models are trained and used for different types of target devices. In an exemplary application of the disclosed methods and systems, a single-die ML model 110 can be applied to a circuit design targeted to a device that consists of a single semiconductor die, and a multi-die ML model 112 can be applied to a circuit design targeted to a device that consists of multiple semiconductor die in a package.

According to an exemplary implementation, the models 110 and 112 can be implemented as binary classifier models. Each classifier model is trained to return a prediction value (a label) indicative of a level of routing congestion. For example, the prediction value can indicate either an acceptable or unacceptable level of routing congestion is likely to result from placement and routing. Random forest models can be used to implement the classifier models, for example. Alternative binary classifier models that could be used in the disclosed methods and systems include decision trees, boosted trees, warm-start classifier methods, support vector machines, convolutional neural networks, or graph neural networks.

Block 114 shows a decision point of the design tool based on the predicted congestion level output from the congestion prediction phase. In response to the predicted congestion level being acceptable, for example less than a threshold, the design tool can bypass assessing the netlist and design for modifications and/or parameters settings and proceed to placement, physical optimization, routing, and realization stages 120, 122, 124, and 126.

Otherwise, at block 116 the design tool can assess the design to identify issues in the optimized netlist that can cause routing congestion. Based on the identified issues, the design tool can take or suggest implementation-flow actions to remedy the issues. Examples of issues that the design tool can identify in the optimized netlist include those relating to high levels of utilization and high fanout nets. One exemplary utilization metric relates to the number of cells of a certain type required in a region of the target device. Another exemplary utilization metric is the number of control sets (combination of set, reset, enable, and clock signals) in the circuit design. For target IC devices such as FPGAs, the level of utilization of look-up table (LUT) RAMs (LUTRAMs) in a region of a target device is another utilization metric.

The design tool can automatically take actions to address the congestion issues or make suggestions to a designer as to the actions that can reduce congestion. Issues found in the netlist that can implicate modifying the design and re-synthesizing can include the presence of any particular block/primitive that can lead to high pin density, such as CARRY8 and MUXF primitives, combined LUTs, a large number of control sets, and high fanout nets not driven by global clock buffers in FPGAs. Modifications that can be made or suggested can include remapping CARRY8 and MUXF primitives into logic LUTs, uncombining the LUTs, decomposing larger LUTs (e.g., LUT6 primitives), and inserting clock buffers on high fanout nets.

Suggestions to the designer for modifying the design can include changing the RTL code so that the synthesizer does not infer redundant logic. The inference of redundant logic can occur based on a forced mapping of a memory variable to registers, which can result in a higher utilization of registers. Another exemplary suggestion can be simplifying highly interconnected modules of the design.

Examples of directives to the processes of the placement stage can direct placement to “bloat” modules, balance super logic regions (SLRs), and balance super long lines (SLLs). LUTs combined aggressively can cause congestion. In response to the bloat directive, for modules in which the pin density is greater than a threshold, the placement processes attempt to place a limited number of cells per CLB in order to reduce demand for routing resources in certain areas. In response to the directive to balance SLRs, the placement processes attempt to distribute the logic placement per SLR, which reduces the level of utilization of resources of an SLR and thereby reduces congestion. Excessive crossing of wide buses through a SLR can lead to SLL congestion and make the design unroutable. The directive to balance SLLs can reduce net crossings through an SLR to reduce congestion and improve timing.

Examples of routing directives include aggressive exploration of routes and no relaxation of timing.

At block 118, the design tool can automatically modify the circuit design based on modifications determined in the assessment stage 116. A designer can also manually modify the design based on the suggested actions determined in the assessment stage 116. For semi-automated or manual modifications, the design tool can present suggested actions associated with identified issues. The design tool can output the suggested actions to a display. A suggested action can be presented in the form a user-selectable display object that has an associated executable procedure. The object can be selected by a point-and-click device, keyboard, voice activation, or touchscreen activation, for example. In response to selection of the object, the design tool initiates execution of the associated executable procedure. The resulting modified circuit design 102′ can then be synthesized, optimized, and subjected to congestion prediction as described above.

In the placement stage at block 120, the design tool places the synthesized design according to the parameter settings selected in the assessment stage 116 or parameter settings selected by the designer. In the physical optimization stage at block 122, the design tool performs recognized optimizations, including, but not limited to, replication of high fanout drivers, retiming, and register re-placement. In the routing stage at block 124, the design tool routes the placed-and-optimized design according to the parameter settings selected in the assessment stage 116 or parameter settings selected by the designer.

The design tool at block 126 performs circuit realization processes, which can include processes to generate implementation data from which an integrated circuit can be made. For targeted devices that are FPGAs, for example, a bitstream generation process (not shown) can input the routed design and generate configuration data for configuring an FPGA device or FPGA resources of a system-on-chip (SoC).

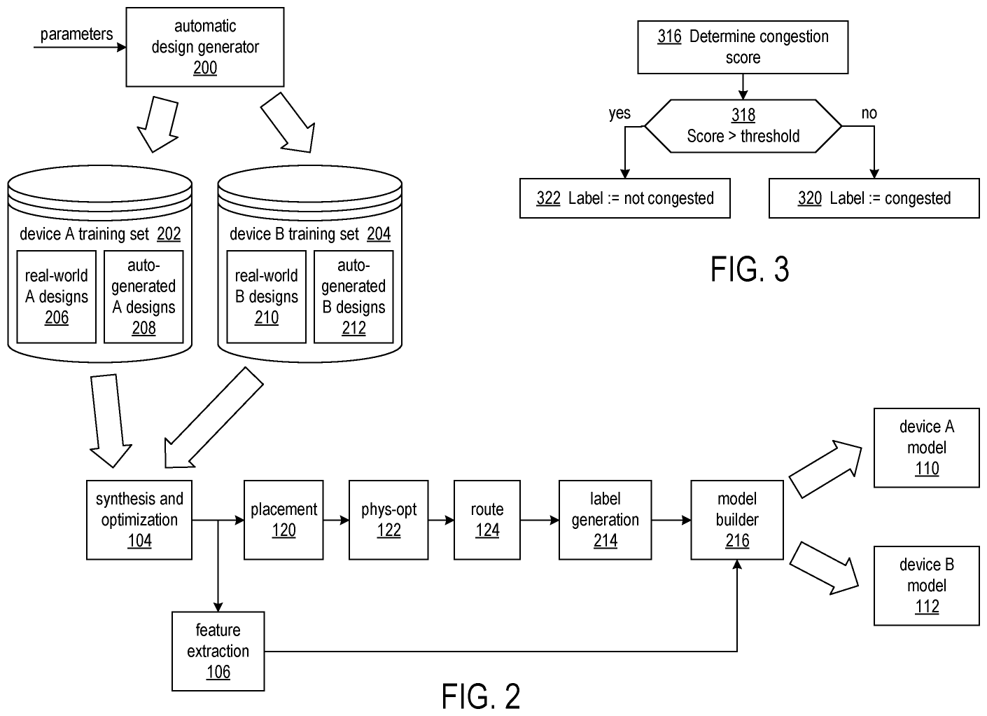

FIG. 2 shows a flowchart of an exemplary process of a training tool for training one or more machine learning models to predict routing congestion in circuit designs. According to the exemplary system, the machine learning models 110 and 112 are random forest classifiers, and the model builder 216 uses an ensemble learning algorithm (based on decision trees) to train the models. To reduce or eliminate overfitting, the training process uses a 4:1 ratio of training designs (“training set”) to test designs (“test set”). That is, there is a 4:1 ratio of the number of designs in the training set to the number of designs in the test set. The designs in the test set are used to ensure that the models perform well on designs different from the designs on which the models were trained. The 4:1 ratio can ensure that the variance of the training parameters and testing metrics are not too high. The fractions of the numbers of long-runtime designs (total time through routing) in the training set and the test set are approximately equal to aid in verification.

The exemplary system uses training set 202 for training ML model 110 and training set 204 for training ML model 112. Each of the training sets 202 and 204 include real-world designs and automatically generated designs. The real-world designs 206 and 210 can include copies of designs that have been implemented and used in commercial, government, education and similar application environments. The auto-generated designs 208 and 212 can include designs generated by an automatic design generator 200. According to an example, 60% of the designs in each of training sets 202 and 204 can be real-world designs, and 40% of the designs can be auto-generated designs. The auto-generated designs can be created to exhibit high congestion by providing values indicating high utilization and/or a high Rent's exponent as parameters to the automatic design generator 200.

The processing of blocks 104, 106, 120, 122, 124, 214, and 216 is performed for each of the designs in training set 202 to train ML model 110, and the processing of blocks 104, 106, 120, 122, 124, 214, and 216 is performed for each of the designs in training set 204 to train ML model 112. The processes of the synthesis and optimization stages at block 104 generate a synthesized netlist, and the processes of the feature extraction stage 106 identify features present in the synthesized netlist as described above. In the placement stage at block 120, the training tool places the synthesized design; in the physical optimization stage at block 122, the training tool performs recognized optimizations; and in the routing stage at block 124, the training tool routes the placed-and-optimized design.

The training tool at block 214 generates a label from the routed design. As the ML models are binary classifier models, the label generation process generates a label having a binary value (e.g., 0 or 1), which can be based on an observed level of congestion as determined by known quality-of-result assessment processes (e.g., FIG. 3).

The label generated by the label generation process is provided to the model builder 216, along with the features identified by the processes of the feature extraction stage 106. As explained above, the machine learning models 110 and 112 are random forest classifiers, and the model builder 216 uses an ensemble learning algorithm (based on decision trees) to train the models.

According to an example implementation, the ML models can be improved by tuning hyper-parameters using a tool such as GridSearchCV. In addition, under-fitting and over-fitting can be reduced by cross-validating the designs of the training sets.

FIG. 3 shows a flowchart of an exemplary process by which a label can be generated in the training of a machine learning model for predicting routing congestion. At block 316, the label generation process determines a score that indicates a level of routing congestion found in the routed design. According to an example, known quality assessment tools can be used to calculate a congestion category score that ranges from 1 to 5, with a score of 1 indicating a very high level of congestion and 5 indicating a very low level of congestion. The congestion category score can represent types of congestion, the number of placement windows that are congested, and the locations of the congested windows.

The label generation process can use a threshold, as shown by decision block 318, to convert the congestion score to a binary value, and different thresholds can be used for different target IC devices. For example, for an exemplary single-die device, the label can be set to congested (1), as exemplified by block 320 in response to the congestion score being less than a threshold 3, and the label can be set to not-congested (0), as exemplified by block 322 in response to the congestion score being greater than the threshold 3. For multi-die devices, a threshold of 2.5 can be used to generate labels.

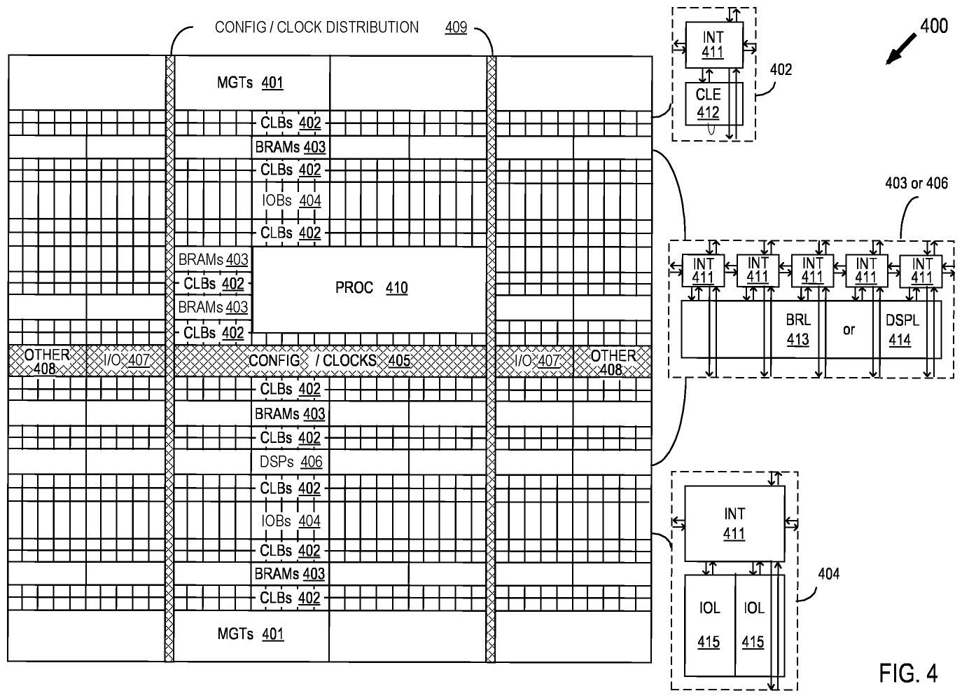

FIG. 4 shows an example of a first type of target IC device that can be implemented on a single semiconductor die. The device 400 is a programmable integrated circuit (IC). FPGA logic may include several different types of programmable logic blocks in the array. For example, FIG. 4 illustrates programmable IC 400 that includes a large number of different programmable tiles including multi-gigabit transceivers (MGTs) 401, configurable logic blocks (CLBs) 402, random access memory blocks (BRAMs) 403, input/output blocks (IOBs) 404, configuration and clocking logic (CONFIG/CLOCKS) 405, digital signal processing blocks (DSPs) 406, specialized input/output blocks (I/O) 407, for example, clock ports, and other programmable logic 408 such as digital clock managers, analog-to-digital converters, system monitoring logic, and so forth. Some programmable IC having FPGA logic also include dedicated processor blocks (PROC) 410 and internal and external reconfiguration ports (not shown).

In some FPGA logic, each programmable tile includes a programmable interconnect element (INT) 411 having standardized connections to and from a corresponding interconnect element in each adjacent tile. Therefore, the programmable interconnect elements taken together implement the programmable interconnect structure for the illustrated FPGA logic. The programmable interconnect element INT 411 also includes the connections to and from the programmable logic element within the same tile, as shown by the examples included at the top of FIG. 4.

For example, a CLB 402 can include a configurable logic element CLE 412 that can be programmed to implement user logic, plus a single programmable interconnect element INT 411. A BRAM 403 can include a BRAM logic element (BRL) 413 in addition to one or more programmable interconnect elements. Typically, the number of interconnect elements included in a tile depends on the height of the tile. The illustrated BRAM tile has the same height as five CLBs, but other numbers (e.g., four) can also be used. A DSP tile 406 can include a DSP logic element (DSPL) 414 in addition to an appropriate number of programmable interconnect elements. An IOB 404 can include, for example, two instances of an input/output logic element (IOL) 415 in addition to one instance of the programmable interconnect element INT 411. As will be clear to those of skill in the art, the actual I/O bond pads connected, for example, to the I/O logic element 415, are manufactured using metal layered above the various illustrated logic blocks, and typically are not confined to the area of the input/output logic element 415.

A columnar area near the center of the die (shown shaded in FIG. 4) is used for configuration, clock, and other control logic. Horizontal areas 409 extending from this column are used to distribute the clocks and configuration signals across the breadth of the programmable IC. Note that the references to “columnar” and “horizontal” areas are relative to viewing the drawing in a portrait orientation.

Some programmable ICs utilizing the architecture illustrated in FIG. 4 include additional logic blocks that disrupt the regular columnar structure making up a large part of the programmable IC. The additional logic blocks can be programmable blocks and/or dedicated logic. For example, the processor block PROC 410 shown in FIG. 4 spans several columns of CLBs and BRAMs.

Note that FIG. 4 is intended to illustrate only an exemplary programmable IC architecture. The numbers of logic blocks in a column, the relative widths of the columns, the number and order of columns, the types of logic blocks included in the columns, the relative sizes of the logic blocks, and the interconnect/logic implementations included at the top of FIG. 4 are purely exemplary. For example, in an actual programmable IC, more than one adjacent column of CLBs is typically included wherever the CLBs appear, to facilitate the efficient implementation of user logic.

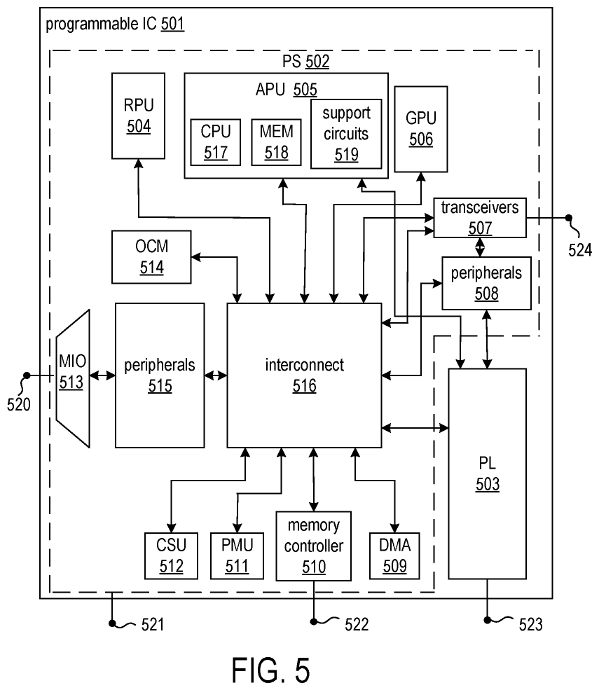

FIG. 5 shows an example of a second type of target IC device that can be implemented on multiple semiconductor dice, such as a System-on-Chip (SoC) 501. In the example, the SoC includes the processing subsystem (PS) 502 and the programmable logic subsystem 503. The processing subsystem 502 includes various processing units, such as a real-time processing unit (RPU) 504, an application processing unit (APU) 505, a graphics processing unit (GPU) 506, a configuration and security unit (CSU) 512, and a platform management unit (PMU) 511. The PS 502 also includes various support circuits, such as on-chip memory (OCM) 514, transceivers 507, peripherals 508, interconnect 516, DMA circuit 509, memory controller 510, peripherals 515, and multiplexed (MIO) circuit 513. The processing units and the support circuits are interconnected by the interconnect 516. The PL subsystem 503 is also coupled to the interconnect 516. The transceivers 507 are coupled to external pins 524. The PL 503 is coupled to external pins 523. The memory controller 510 is coupled to external pins 522. The MIO 513 is coupled to external pins 520. The PS 502 is generally coupled to external pins 521. The APU 505 can include a CPU 517, memory 518, and support circuits 519. The APU 505 can include other circuitry, including L1 and L2 caches and the like. The RPU 504 can include additional circuitry, such as L1 caches and the like. The interconnect 516 can include cache-coherent interconnect or the like.

Referring to the PS 502, each of the processing units includes one or more central processing units (CPUs) and associated circuits, such as memories, interrupt controllers, direct memory access (DMA) controllers, memory management units (MMUs), floating point units (FPUs), and the like. The interconnect 516 includes various switches, busses, communication links, and the like configured to interconnect the processing units, as well as interconnect the other components in the PS 502 to the processing units.

The OCM 514 includes one or more RAM modules, which can be distributed throughout the PS 502. For example, the OCM 514 can include battery backed RAM (BBRAM), tightly coupled memory (TCM), and the like. The memory controller 510 can include a DRAM interface for accessing external DRAM. The peripherals 508, 515 can include one or more components that provide an interface to the PS 502. For example, the peripherals can include a graphics processing unit (GPU), a display interface (e.g., DisplayPort, high-definition multimedia interface (HDMI) port, etc.), universal serial bus (USB) ports, Ethernet ports, universal asynchronous transceiver (UART) ports, serial peripheral interface (SPI) ports, general purpose (GPIO) ports, serial advanced technology attachment (SATA) ports, PCle ports, and the like. The peripherals 515 can be coupled to the MIO 513. The peripherals 508 can be coupled to the transceivers 507. The transceivers 507 can include serializer/deserializer (SERDES) circuits, MGTs, and the like.

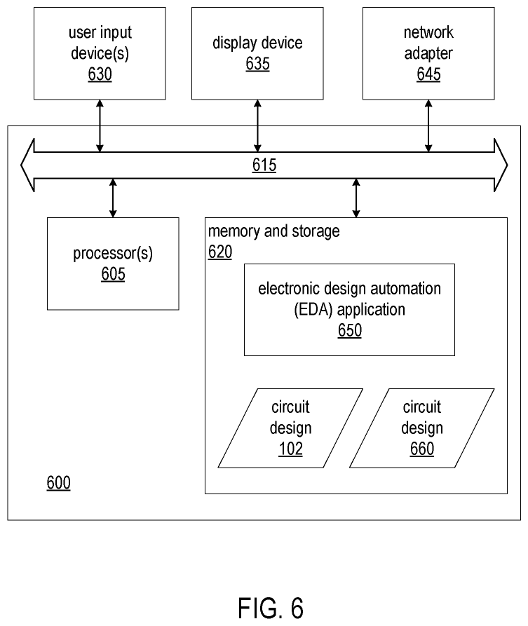

FIG. 6 is a block diagram illustrating an exemplary data processing system (system) 600. System 600 is an example of an EDA system. As pictured, system 600 includes at least one processor circuit (or “processor”), e.g., a central processing unit (CPU) 605 coupled to memory and storage arrangement 620 through a system bus 615 or other suitable circuitry. System 600 stores program code and circuit design 102 within memory and storage arrangement 620. Processor 605 executes the program code accessed from the memory and storage arrangement 620 via system bus 615. In one aspect, system 600 is implemented as a computer or other data processing system that is suitable for storing and/or executing program code. It should be appreciated, however, that system 600 can be implemented in the form of any system including a processor and memory that is capable of performing the functions described within this disclosure.

Memory and storage arrangement 620 includes one or more physical memory devices such as, for example, a local memory (not shown) and a persistent storage device (not shown). Local memory refers to random access memory or other non-persistent memory device(s) generally used during actual execution of the program code. Persistent storage can be implemented as a hard disk drive (HDD), a solid state drive (SSD), or other persistent data storage device. System 600 may also include one or more cache memories (not shown) that provide temporary storage of at least some program code and data in order to reduce the number of times program code and data must be retrieved from local memory and persistent storage during execution.

Input/output (I/O) devices such as user input device(s) 630 and a display device 635 may be optionally coupled to system 600. The I/O devices may be coupled to system 600 either directly or through intervening I/O controllers. A network adapter 645 also can be coupled to system 600 in order to couple system 600 to other systems, computer systems, remote printers, and/or remote storage devices through intervening private or public networks. Modems, cable modems, Ethernet cards, and wireless transceivers are examples of different types of network adapter 645 that can be used with system 600.

Memory and storage arrangement 620 may store an EDA application 650. EDA application 650, being implemented in the form of executable program code, is executed by processor(s) 605. As such, EDA application 650 is considered part of system 600. System 600, while executing EDA application 650, receives and operates on circuit design 302. In one configuration, system 600 operates as a training tool to construct ML models 110 and 112. In another configuration, system 600 operates as a design tool to process an input circuit design and apply an ML model as described above. System 600 generates data suitable for making an IC as circuit design 660.

EDA application 650, circuit design 102, circuit design 660, and any data items used, generated, and/or operated upon by EDA application 650 are functional data structures that impart functionality when employed as part of system 600 or when such elements, including derivations and/or modifications thereof, are loaded into an IC such as a programmable IC causing implementation and/or configuration of a circuit design within the programmable IC.

Some implementations are directed to a computer program product (e.g., nonvolatile memory device), which includes a machine or computer-readable medium having stored thereon instructions which may be executed by a computer (or other electronic device) to perform these operations/activities

Though aspects and features may in some cases be described in individual figures, it will be appreciated that features from one figure can be combined with features of another figure even though the combination is not explicitly shown or explicitly described as a combination.

The methods and system are thought to be applicable to a variety of approaches for improving circuit designs. Other aspects and features will be apparent to those skilled in the art from consideration of the specification. The methods and system may be implemented as one or more processors configured to execute software, as an application specific integrated circuit (ASIC), or as a logic on a programmable logic device. It is intended that the specification and drawings be considered as examples only, with a true scope of the invention being indicated by the following claims.

What is claimed is:

1. A method comprising:
synthesizing a circuit design into a netlist by a design tool;
identifying features from the netlist by the design tool;
applying a congestion prediction model to the features by the design tool prior to placement, wherein application of the congestion prediction model generates a prediction value indicative of a congestion level likely to result from placement and routing of the netlist; and
in response to the prediction value indicating the congestion level is greater than a threshold:
determining an implementation-flow action by the design tool, and
performing the implementation-flow action to generate implementation data that is suitable for making an integrated circuit (IC).

2. The method of claim 1, wherein:
the determining includes determining parameter settings for a placement process or a routing process of the design tool; and
the performing includes executing by the design tool, the placement process and the routing process using the parameters settings.

3. The method of claim 2, further comprising bypassing determining the parameter settings and executing the placement process and the routing process of the design tool in response to the prediction value indicating the congestion level is less than a threshold.

4. The method of claim 1, wherein:
the determining includes determining modifications to make to the circuit design; and
the performing includes modifying the circuit design to include the modifications.

5. The method of claim 1, further comprising selecting, in response to an input parameter to the design tool specifying one of a first type target integrated circuit (IC) device or a second-type target IC device, the congestion prediction model from a first congestion prediction model and a second congestion prediction model, wherein the first congestion prediction model is associated with the first type target IC device, and the second congestion prediction model is associated with the second type target IC device.

6. The method of claim 5, wherein the first type target IC device is a single semiconductor die targeted to implement the circuit design, and the second type target IC device includes a package of two or more semiconductor dice targeted to implement the circuit design.

7. The method of claim 1, wherein:
the circuit design is targeted for implementation on a target integrated circuit (IC) device; and
identifying the features includes determining one or more levels of utilization by the netlist of one or more types of circuit elements, respectively, of the target IC device.

8. The method of claim 1, wherein:
the circuit design is targeted for implementation on a target integrated circuit (IC) device; and
the features include an indicator that a count of high-fanout nets is greater than a first threshold, and a net having a count of fanouts greater than a second threshold is a high-fanout net.

9. The method of claim 1, wherein identifying the features includes estimating a worst negative slack and a worst hold slack from the netlist, and the features includes the worst negative slack and the worst hold slack.

10. The method of claim 1, wherein:
the circuit design is targeted for implementation on a target integrated circuit (IC) device; and
identifying the features includes indicating a number of programmable processors and a number of transceivers available on the target IC device.

11. The method of claim 1, wherein identifying the features includes estimating interconnection complexity from the netlist using Rent's rule.

12. A method comprising:
synthesizing and performing logic optimization on circuit designs of a training set to generate respective netlists by a design tool;
determining respective feature sets of the netlists by the design tool;
performing placement and routing on the netlists to generate placed-and-routed designs;
determining respective congestion levels from the placed-and-routed designs; and
training a classification model using the respective features sets and respective congestion levels.

13. The method of claim 12, wherein:
the circuit designs are targeted for implementation on a target integrated circuit (IC) device; and
determining the respective feature sets includes determining for each circuit design, one or more levels of utilization by the netlist of one or more types of circuit elements, respectively, of the target IC device.

14. The method of claim 12, wherein:
the circuit designs are targeted for implementation on a target integrated circuit (IC) device; and
determining the respective feature sets includes determining for each circuit design, a high-fanout indicator.

15. The method of claim 12, wherein determining the respective feature sets includes estimating a worst negative slack and a worst hold slack from each netlist, and each feature set includes the worst negative slack and the worst hold slack.

16. The method of claim 12, wherein:
the circuit designs are targeted for implementation on a target integrated circuit (IC) device; and
determining the respective feature sets includes indicating a number of programmable processors and a number of transceivers available on the target IC device.

17. A system comprising:
one or more computer processors configured to execute program code; and
a memory arrangement coupled to the one or more computer processors, wherein the memory arrangement is configured with instructions of a design tool that when executed by the one or more computer processors cause the one or more computer processors to perform operations including:
synthesizing a circuit design into a netlist;
identifying features from the netlist;
applying a congestion prediction model to the features prior to placement, wherein application of the congestion prediction model generates a prediction value indicative of a congestion level likely to result from placement and routing of the netlist; and
in response to the prediction value indicating the congestion level is greater than a threshold:
determining an implementation-flow action, and
performing the implementation-flow action to generate implementation data that is suitable for making an integrated circuit (IC).

18. The system of claim 17, wherein:
the instructions for determining the implementation-flow action include instructions for determining parameter settings for a placement process or a routing process of the design tool; and
the instructions for performing the implementation-flow action include instructions for executing the placement process and the routing process using the parameters settings.

19. The system of claim 18, wherein the instructions of the design tool includes instructions for bypassing determining the parameter settings and executing the placement process and the routing process of the design tool in response to the prediction value indicating the congestion level is less than a threshold.

20. The system of claim 17, wherein:
the instructions for determining the implementation-flow action include instructions for determining modifications to make to the circuit design; and
the instructions for performing the implementation-flow action include instructions for modifying the circuit design to include the modifications.
